(19) United States
(12) Patent Application Publication
(10) Pub. No.: US 2011/0163821 A1
(43) Pub. Date: Jul. 7, 2011

(54) PIEZOELECTRIC VIBRATOR AND OSCILLATION CIRCUIT USING THE SAME

(76) Inventors: Hiroyuki Souma, Chiba-shi (JP); Seigo Fukuchi, Chiba-shi (JP); Satoshi Shimizu, Chiba-shi (JP)

(21) Appl. No.: 13/048,334

(22) Filed: Mar. 15, 2011

Related U.S. Application Data
(63) Continuation of application No. PCT/JP2009/004261, filed on Aug. 31, 2009.

(30) Foreign Application Priority Data
Sep. 17, 2008 (JP) 2008-238273

(51) Int. Cl. H03B 5/12

(52) U.S. Cl. 331/117 FE

(57) ABSTRACT

In a circuit including a CMOS inverter (inverting amplifier) (IV02), a floating capacitance resulting from the circuit and peripheral interconnections thereof is Cs, a capacitive element (Cg) is connected to the input side of the CMOS inverter (inverting amplifier) (IV02), a capacitive element (Cd) is connected to the output side thereof, and the capacitances of the capacitive element (Cg) and the capacitive element (Cd) are determined (tuned) so that a load capacitance (CL) of a piezoelectric vibrator (X2) satisfies a relational expression “CL=Cs+Cg×Cd/(Cg+Cd)”. By determining the capacitances of the capacitive element (Cg) and the capacitive element (Cd) in this way, it is possible to improve the oscillation frequency stability with respect to a variation in capacitance value of the load capacitance (CL) in a region of a low load capacitance (CL) (for example, 3 pF).

### RELATED APPLICATIONS

This application is a continuation of PCT/JP2009/004261 filed on Aug. 31, 2009, which claims priority to Japanese Application No. 2008-238273 filed on Sep. 17, 2008. The entire contents of these applications are incorporated herein by reference.

### BACKGROUND OF THE INVENTION

1. Field of the Invention

The present invention relates to a piezoelectric element used in an oscillation circuit built in a portable device such as a mobile terminal and an oscillation circuit using the piezoelectric element.

This application is based on and claims the priority of Japanese Patent Application No. 2008-238273, filed on Sep. 17, 2008, the contents of which are incorporated herein by reference.

2. Description of the Related Art

As shown in FIG. 3, a portable device 1 such as a mobile phone includes a system LSI 10 mounted with a circuit block performing a variety of functions of the portable device, an RF module 11 communicating with an external device, a base station, and the like, a power supply controller 12, and a battery pack 13.

The system LSI 10 is further mounted with an oscillation circuit 20 generating a system clock and is externally mounted with a piezoelectric vibrator 20A such as a crystal vibrator constituting the oscillation circuit 20.

In the portable device having the above-mentioned configuration, driving for a long time is required to reduce the number of times of charging a battery, and it is intended to reduce power consumption of the oscillation circuit when the oscillation circuit is in the standby state (when the oscillation circuit is in an oscillated state and in a non-loaded state) or to extend the lifetime based on a voltage/power supply method.

In a semiconductor integrated circuit in which an internal source voltage is controlled, a circuit has been proposed in which low power consumption control is performed in the standby state and the amplitude Vd of a drain potential at the time of oscillation in a CMOS inverter constituting an oscillation gate in an oscillation circuit employing a piezoelectric oscillator is controlled using a dropped internal source voltage and the charging and discharging current of a capacitor externally connected to an output side of the CMOS inverter is reduced to reduce the power consumption of the oscillation circuit (for example, see PTL 1).

In an oscillation circuit employing a piezoelectric oscillator and using a CMOS inverter as an oscillation gate, an oscillation circuit has been proposed in which the load capacitance is reduced in the initial state of the oscillation operation, a negative resistance is maintained to such an extent to obtain an excellent oscillation-starting characteristic, the mutual conductance Gm of the CMOS inverter is reduced by the reduction of the load capacitance to reduce power consumption, by disconnecting a capacitive element from the CMOS inverter of an oscillation amplifier by the use of a switching element in an initial state of an oscillation operation (for example, see PTL 2).

In the oscillation circuit employing the piezoelectric vibrator described above, there is a need for microminiaturization in size and weight of the piezoelectric vibrator used in the oscillation circuit. FIG. 4 shows the relationship between the size of the piezoelectric vibrator, the consumption current, and an oscillation margin (oscillation stability). As shown in the drawing, the piezoelectric vibrator has a feature that a crystal impedance value (CI value), that is, the series equivalent resistance value (effective resistance value) R1, increases as the size decreases and the consumption current increases, thereby lowering the oscillation margin. That is, in order to stably oscillate the piezoelectric oscillator, it is necessary to design the negative resistance (oscillation margin) of the oscillation circuit as much as possible, and the oscillation may be stopped when the negative resistance does not have a satisfactory magnitude. Accordingly, five or more times the upper limit rating of series equivalent resistance is generally recommended as the value of the negative resistance.

In a power-saved oscillation circuit of the portable device, the value (CI value) necessary for the small-size and small-thickness piezoelectric vibrator tends to increase and the decrease in power consumption required for the oscillation circuit and the crystal impedance value of the piezoelectric vibrator have a trade-off relation.

Here, a specific circuit configuration of a conventional oscillation circuit using the CMOS inverter and the piezoelectric vibrator is described. FIG. 5 shows the configuration of a conventional oscillation circuit including a piezoelectric vibrator. The oscillation circuit shown in the drawing includes an inverter (inverting amplifier) IV01 having a CMOS structure, a resistor Rf externally connected to an input terminal XCIN and an output terminal XCOUT, a piezoelectric vibrator X1 such as a crystal vibrator, and capacitive elements (capacitors) C1 and C2 controlling a load capacitance. The CMOS inverter IV01 and the resistor Rf constitutes an inverting amplifier, the input terminal thereof is connected to the input terminal XCIN, and the output terminal thereof is connected to the output terminal XCOUT.

The CMOS inverter IV01 includes a PMOS transistor PM1 and an NMOS transistor NM1 connected in series between the source voltage Vdd and the ground potential Vss. The gates of the transistors are connected to the input terminal XCIN and the drains thereof are connected to the output terminal XCOUT. FIG. 6 shows an equivalent circuit of the CMOS inverter IV01. In the drawing, Vd represents a drain voltage, Vg represents a gate voltage, GmVg represents a current source, Idd (I1) represents a saturated drain current, G represents a gate electrode, D represents a drain electrode, and S represents a source electrode.

In the oscillation circuit, the CMOS inverter IV01 and the piezoelectric vibrator X1 constitute a positive feedback loop to perform an oscillation operation. In the configuration, at the time of oscillation, a driving current I₁ flows in the PMOS transistor PM1, a through-current I₁₀ flows in the NMOS transistor NM1, an output current I₁₁ flows in the output side, a charging and discharging current I₂ flows in the capacitive element C2, and an excitation current I_{X} flows in the capacitive element C1 and the piezoelectric vibrator X1. Out of the currents, the sum of the through-current I₁₀, the charging and discharging current I₂ flowing in the capacitive element C2 constituting the load capacitance, and the excitation current I_{X} flowing in the capacitive element C1 and the piezoelectric vibrator X1 constitutes the consumption current.

In the configuration, the load capacitance CL appears as an effective series equivalent capacitance as the oscillation circuit is viewed from both terminals of the piezoelectric vibrator (crystal vibrator) X1, and the load capacitance CL of the vibrator and the load capacitance of the oscillation circuit are set to be matched with each other. In the conventional oscillation circuit shown in FIG. 5, for example, when the oscillation frequency is 32 kHz, the load capacitance formed by the circuit of the CMOS inverter IV01 and the combined capacitance CL1 of the capacitive elements C1 and C2 is set to about 12.5 pF and the load capacitance CL of the piezoelectric vibrator X1 is set to 12.5 pF (conventional standard value) so as to be matched with the load capacitance of the oscillation circuit.

The present applicant previously filed an oscillation circuit obtained by improving the oscillation circuit shown in FIG. 5, that is, a circuit in which the decrease (the decrease in CL value) of the load capacitance CL of the piezoelectric vibrator X1 is accomplished (see PTL 3).

### CITATION LIST

### Patent Literature

[PTL 1] JP-A-2005-159786
[PTL 2] JP-A-2002-344241
[PTL 3] JP-A-2008-205658

As described above, it is preferable that the power consumption is reduced in performing the primary functions of the portable device. In order to reduce the driving current of the piezoelectric vibrator in the oscillation circuit, the mutual conductance Gm of the CMOS inverter should be reduced. In addition, the mutual conductance Gm of the CMOS inverter is determined depending on the source voltage of the oscillation circuit and the CMOS structure.

Here, the oscillation margin M of the oscillation circuit is calculated by the following expression, where ω represents an angular frequency of an oscillation frequency, C1 and C2 represent capacitances of capacitors externally connected between the input terminal and output terminal of the CMOS inverter serving as an oscillation gate of the oscillation circuit and the power source terminal, RL represents a negative resistance, R1 represents an effective resistance of the piezoelectric vibrator, and R1 (max) represents the maximum value of the effective resistance.

M=|−Gm|/(ω²C1·C2)×1/R1(max)=+RL/R1(max) (1)

The oscillation margin M needs to have a value equal to or greater than 5.

When it is reviewed from the viewpoint of the piezoelectric vibrator to accomplish the decrease in power consumption and the stabilization of oscillation in the oscillation circuit, the effective resistance R1 of the piezoelectric vibrator is a value determined by the requirement for a decrease in size of the piezoelectric vibrator and cannot be excessively lowered concerning the decrease in size of the piezoelectric vibrator.

Therefore, in order to keep the oscillation margin at such a value to stabilize the oscillation, it can be seen from Expression 1 that it can be realized by lowering the capacitance value of the capacitor constituting the load capacitance and being externally connected to the CMOS inverter, that is, the capacitance value of the load capacitance.

Accordingly, the present applicant previously filed an oscillation circuit having a piezoelectric vibrator with a low load capacitance CL (which satisfies 3 pF≦CL<5 pF) which is suitable as a low power consumption specification required for an integrated circuit to be mounted therewith (see PTL 3).

FIG. 7 shows the configuration of the oscillation circuit described in PTL 3 previously filed. Details of the circuit shown in FIG. 7 will be described again later in the section of Description of Embodiments and thus are described herein briefly.

In the oscillation circuit shown in FIG. 7, the capacitance value of the capacitive elements (capacitors) C1 and C2 constituting the load capacitance and being externally connected to the CMOS inverter IV02, that is, the capacitance value of the load capacitance, is lowered by providing driving-current-controlling resistive elements r1 and r2 limiting the driving current for exciting the piezoelectric vibrator. The value of the load capacitance is a combined capacitance value of the capacitance value of the capacitive element externally connected to the oscillation circuit (oscillation gate) along with the piezoelectric vibrator and the floating capacitance generated at the time of connection to the oscillation circuit, and the load capacitance CL of the piezoelectric vibrator is also set to a value suitable for the load capacitance of the circuit.

When the oscillation gate shown in FIG. 7 includes the CMOS inverter, the floating capacitance is in the range of about 1 to 2 pF due to the limitation in manufacturing the CMOS semiconductor device and the piezoelectric vibrator with a low load capacitance of about 6 pF exists. Accordingly, the capacitance value of the load capacitance CL of the piezoelectric vibrator with a low load capacitance is determined as in the range of 3 pF≦CL<5 pF.

In this way, the circuit of FIG. 7 in which the load capacitance CL is reduced (3 pF≦CL<5 pF), the decrease in power consumption is accomplished in the standby state of the oscillation circuit, but problems with the allowable capacitance error ΔC of the load capacitance CL and the frequency deviation Δf of the oscillation frequency are remarkable due to the decrease in the load capacitance CL.

For example, FIG. 17 is a diagram illustrating the relationship between the frequency deviation Δf (ppm) and the load capacitance CL (pF), where a characteristic curve indicating a variation of the frequency deviation Δf (ppm) generated when the load capacitance CL varies by 1 pF for each capacitance value of the load capacitance CL is shown.

In the characteristic curve shown in FIG. 17, when the load capacitance CL indicated by point A is 12.5 pF, the characteristic curve varies at a rate of a slope S (=−6 ppm/pF) every variation of the load capacitance CL by 1 pF. When the load capacitance CL indicated by point B is 6 pF, the characteristic curve varies at a rate of a slope S (=−22 ppm/pF) every variation of the load capacitance CL by 1 pF. When the load capacitance CL indicated by point C is 3 pF, the characteristic curve varies at a rate of a slope S (=−68 ppm/pF) every variation of the load capacitance CL by 1 pF.

That is, when the slope S (=−6 ppm/pF) at the load capacitance CL of 12.5 pF is assumed as 1 and the load capacitance CL is 6 pF, the frequency deviation (ppm) is generated at four times the rate with 12.5 pF. When the load capacitance CL is 3 pF, the frequency deviation (ppm) is generated at 12 times the rate with 12.5 pF. Accordingly, when the load capacitance CL is lowered, it is necessary to increase the precision of the capacitance values of the load capacitance in the oscillation circuit and the load capacitance in the piezoelectric vibrator, but it is difficult to lower the load capacitance CL due to the manufacturing variations.

FIG. 18 is a diagram illustrating the stability of the oscillation frequency with respect to the allowable capacitance error, where the oscillation frequency stability Δf (ppm) when the load capacitance CL varies by ΔC (±5%) which is the normal allowable capacitance error is shown. As indicated by point A in FIG. 18, when the load capacitance CL is 12.5 pF, ΔC is 1.25 pF and the oscillation frequency stability Δf is 7.3 ppm. As indicated by point B, when the load capacitance CL is 6 pF, ΔC is 0.6 pF and the oscillation frequency stability Δf is 13.2 ppm. As indicated by point C, when the load capacitance CL is 3 pF, ΔC is 0.3 pF and the oscillation frequency stability Δf is 20.5 ppm.

That is, when the frequency stability Δf (7.3 ppm/pF) at the load capacitance CL of 12.5 pF is assumed as 1 and the load capacitance CL is 6 pF, the frequency deviation (ppm) is generated at 1.8 times the rate with 12.5 pF. When the load capacitance CL is 3 pF, the frequency deviation (ppm) is generated at 2.8 times the rate with 12.5 pF.

In this way, with the low load capacitance CL (for example, 3 pF), the frequency deviation increases by 2.8 times that with 12.5 pF. Accordingly, in order to reduce the load capacitance CL (the decrease in CL), it is necessary to improve the frequency stability with respect to the allowable capacitance error (±5%).

### SUMMARY OF THE INVENTION

The invention is made in consideration of the above-mentioned circumferences. A goal of the invention is to provide a piezoelectric vibrator which can accomplish a decrease in power consumption without adversely affecting an oscillation-starting characteristic and a steady stable operation and can improve the oscillation frequency stability with respect to a variation in load capacitance CL by reducing the load capacitance CL of a piezoelectric vibrator, and an oscillation circuit employing the piezoelectric vibrator.

To accomplish the above-mentioned goal, according to an aspect of the invention, there is provided a piezoelectric vibrator which is connected to an oscillation circuit formed on an integrated circuit, wherein the piezoelectric vibrator has a load capacitance CL substantially equal to a floating capacitance Cs formed by the oscillation circuit of the integrated circuit or a load capacitance CL larger by a predetermined capacitance than the floating capacitance Cs, and a load capacitance of the oscillation circuit connected to the piezoelectric vibrator is matched with the load capacitance CL of the piezoelectric vibrator by the use of a capacitive element.

The piezoelectric vibrator having the above-mentioned configuration has a load capacitance CL substantially equal to the floating capacitance Cs of the oscillation circuit or the load capacitance CL larger by a predetermined capacitance than the floating capacitance Cs.

For example, as shown in FIG. 1, in a circuit including a CMOS inverter IV02, a floating capacitance resulting from the circuit and peripheral interconnections thereof is Cs, a capacitive element Cg is disposed on the input side of the CMOS inverter IV02, a capacitive element Cd is disposed on the output side thereof, and the capacitances of the capacitive element Cg and the capacitive element Cd are determined (matched) so that a load capacitance CL of a piezoelectric vibrator X2 satisfies a relational expression of “CL=Cs+Cg×Cd/(Cg+Cd)”. By determining the capacitances of the capacitive element Cg and the capacitive element Cd in this way, it is possible to improve the oscillation frequency stability with respect to the variation of the load capacitance CL in a region of a low load capacitance CL (for example, 3 pF), as indicated by characteristic curve B in FIG. 2.

Accordingly, it is possible to reduce the load capacitance CL of the piezoelectric vibrator, thereby accomplishing a decrease in power consumption and improving the stability of an oscillation frequency with respect to the variation of the load capacitance CL.

In the piezoelectric vibrator of the aspect of the invention, the floating capacitance Cs of the oscillation circuit may be in the range of about 1 pF to about 4 pF, and the load capacitance CL may be in the range of about 3 pF to about 5 pF.

Accordingly, a piezoelectric vibrator with a load capacitance CL of 3 pF to 5 pF can be selected and used for the oscillation circuit with a floating capacitance Cs of 1 pF to 4 pF. For example, 3 pF, 3.7 pF, 4.4 pF, 5.0 pF, and the like can be normally determined as the load capacitance CL of the piezoelectric vibrator.

According to another aspect of the invention, there is provided an oscillation circuit including: a CMOS semiconductor circuit formed on an integrated circuit; and a piezoelectric vibrator connected to the CMOS semiconductor circuit, wherein the piezoelectric vibrator has a load capacitance CL substantially equal to a floating capacitance Cs formed by the CMOS semiconductor circuit or a load capacitance CL larger by a predetermined capacitance than the floating capacitance Cs, and a capacitive element that matches a load capacitance of the CMOS semiconductor circuit connected to the piezoelectric vibrator with the load capacitance CL of the piezoelectric vibrator is provided.

In the oscillation circuit including a CMOS semiconductor circuit and a piezoelectric vibrator connected to the CMOS semiconductor circuit, the piezoelectric vibrator has a load capacitance CL substantially equal to a floating capacitance Cs formed by the CMOS semiconductor circuit or a load capacitance CL larger by a predetermined capacitance than the floating capacitance Cs. The load capacitance CL of the piezoelectric vibrator and a load capacitance of the CMOS semiconductor circuit connected to the piezoelectric vibrator are matched by the use of a capacitive element.

Accordingly, it is possible to reduce the load capacitance CL of the piezoelectric vibrator, thereby accomplishing a decrease in power consumption and improving the stability of an oscillation frequency with respect to the variation of the load capacitance CL.

In the oscillation circuit, the floating capacitance Cs formed by the CMOS semiconductor circuit may be in the range of about 1 pF to about 4 pF, and the load capacitance CL may be in the range of about 3 pF to about 5 pF.

Accordingly, a piezoelectric vibrator with a load capacitance CL of 3 pF to 5 pF can be selected and used for the oscillation circuit with a floating capacitance Cs of 1 pF to 4 pF. For example, 3 pF, 3.7 pF, 4.4 pF, 5.0 pF, and the like can be normally determined as the load capacitance CL of the piezoelectric vibrator.

In the oscillation circuit, the CMOS semiconductor circuit may include a CMOS inverter, the piezoelectric vibrator may be connected between input and output terminals of the CMOS inverter, and a first capacitive element Cg connected between the input terminal of the CMOS inverter and the ground potential Vss and a second capacitive element Cd connected between the output terminal of the CMOS inverter and the ground potential Vss may be provided. Here, the capacitances of the first capacitive element Cg and the second capacitive element Cd may be determined so that the load capacitance CL of the piezoelectric vibrator satisfies a relational expression of CL=Cs+Cg×Cd/(Cg+Cd).

Regarding the oscillation circuit having the above-mentioned configuration, as shown in FIG. 1, in a circuit including a CMOS inverter IV02, a floating capacitance resulting from the circuit and peripheral interconnections thereof is Cs, a capacitive element Cg is disposed on the input side of the CMOS inverter IV02, a capacitive element Cd is disposed on the output side thereof, and the capacitances of the capacitive element Cg and the capacitive element Cd are determined (matched) so that a load capacitance CL of a piezoelectric vibrator X2 satisfies a relational Expression of “CL=Cs+Cg×Cd/(Cg+Cd)”. By determining the capacitances of the capacitive element Cg and the capacitive element Cd in this way, it is possible to improve the oscillation frequency stability with respect to the variation of the load capacitance CL in a region of a low load capacitance CL (for example, 3 pF), as indicated by characteristic curve B in FIG. 2.

Accordingly, it is possible to reduce the load capacitance CL of the piezoelectric vibrator, thereby accomplishing a decrease in power consumption and improving the stability of an oscillation frequency with respect to the variation of the load capacitance CL.

According to the invention, it is possible to reduce the load capacitance CL of the piezoelectric vibrator, thereby accomplishing a decrease in power consumption and improving the stability of an oscillation frequency with respect to the variation of the load capacitance CL.

### BRIEF DESCRIPTION OF THE DRAWINGS

FIG. 1 is a circuit diagram illustrating the configuration of an oscillation circuit according to an embodiment of the invention.

FIG. 2 is a diagram illustrating stability of an oscillation frequency with respect to an allowable capacitance error ΔC of a load capacitance CL.

FIG. 3 is a block diagram schematically illustrating the configuration of a portable device.

FIG. 4 is a diagram illustrating the relationship between the size of a piezoelectric vibrator, the current consumption, and the oscillation margin.

FIG. 5 is a circuit diagram illustrating the configuration of an oscillation circuit including a conventional piezoelectric vibrator.

FIG. 6 is a diagram illustrating a current source equivalent circuit of a CMOS inverter.

FIG. 7 is a circuit diagram illustrating the configuration of an improved oscillation circuit.

FIG. 8 is a diagram illustrating measured values and calculated values of characteristic data representing the relation between a load capacitance CL and a negative resistance RL.

FIG. 9 is a characteristic diagram illustrating the relation of the negative resistance RL with respect to the load capacitance CL.

FIG. 10 is a diagram illustrating characteristic data representing the relation between the load capacitance CL and an charging and discharging current Id.

FIG. 11 is a characteristic diagram illustrating the relation between the load capacitance CL and the charging and discharging current Id.

FIG. 12 is a circuit diagram illustrating an equivalent circuit of a piezoelectric vibrator.

FIGS. 13 (A) and (B) are each a diagram illustrating the limitation of the load capacitance when the piezoelectric vibrator is connected to a system LSI.

FIG. 14 is a diagram illustrating an example of a suitable value of a feedback resistance Rf when a cutoff frequency Fc is set to ⅓ or less of an oscillation frequency fL of the oscillation circuit.

FIG. 15 is a diagram illustrating characteristic data representing the relation of the load capacitance CL and the negative resistance RL with respect to the cutoff frequency Fc.

FIG. 16 is a characteristic diagram illustrating the relation of the negative resistance RL with respect to the load capacitance CL.

FIG. 17 is a diagram illustrating the frequency stability in the oscillation circuit shown in FIG. 7.

FIG. 18 is a diagram illustrating the stability of the oscillation frequency depending on an allowable capacitance error in the oscillation circuit shown in FIG. 7.

FIG. 19 is a diagram illustrating the characteristics of the load capacitance CL and the oscillation frequency deviation AI

FIG. 20 is a diagram illustrating an example of characteristic data representing the oscillation frequency deviation depending on a capacitance error of an external capacitive element (capacitor) at a floating capacitance of Cs=2.5 pF.

FIG. 21 is a diagram illustrating an example of a combination of the floating capacitance Cs and the low load capacitance CL in which the oscillation frequency deviation (Δf)_{CL} is more stabilized than that at a load capacitance of CL=12.5 pF.

FIG. 22 is a diagram illustrating an example of a combination of a floating capacitance Cs and an external capacitive element (capacitor) at a load capacitance of CL=12.5 pF which is normally used and the oscillation frequency deviation (Δf)_{CL}.

FIG. 23 is a diagram illustrating the comparison result of combination 2 (at a load capacitance of CL=3.7 pF) shown in FIG. 21 and combination 2 shown in FIG. 22, where the floating capacitance is the same as each other.

FIG. 24 is a diagram illustrating an example of a substrate layout of the oscillation circuit according to an embodiment of the invention.

### DETAILED DESCRIPTION OF THE PREFERRED EMBODIMENTS

Hereinafter, an embodiment of the invention will be described with reference to the accompanying drawings. An oscillation circuit according to the invention is obtained by improving an oscillation circuit (the oscillation circuit described in PTL 3 previously filed by the present applicant) as an improvement of the oscillation circuit having a conventional piezoelectric vibrator so as to enhance the stability. Accordingly, the oscillation circuit described in PTL 3 and the oscillation circuit according to the invention have the same basic configuration and have a lot of common configurations. For this reason, the oscillation circuit described in PTL 3 previously filed by the present applicant will be described before describing an embodiment of the invention.

### (Configuration of Oscillation Circuit (PTL 3) Previously Filed by the Present Applicant)

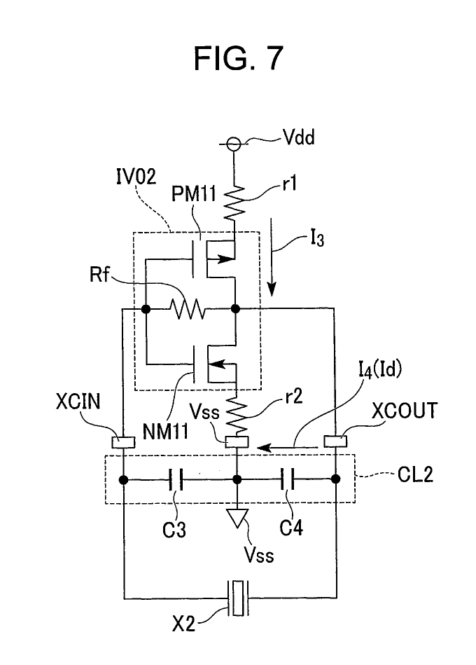

The configuration of the oscillation circuit described in PTL 3 previously filed by the present applicant is shown in FIG. 7. The oscillation circuit shown in FIG. 7 is an example of a circuit in which the load capacitance CL is reduced to 3 pF≦CL<5 pF (conventionally, 12.5 pF) to accomplish a decrease in power consumption.

The oscillation circuit shown in FIG. 7 includes a CMOS inverter IV02 serving as an inverting amplifier, a piezoelectric vibrator X2 such as a crystal vibrator connected between the input terminal XCIN and the output terminal XCOUT of the CMOS inverter IV02, and capacitive elements C3 and C4, which constitute a load capacitance, connected between the input terminal XCIN and the output terminal XCOUT of the CMOS inverter IV02 and a voltage source terminal Vss with the ground potential Vss.

The CMOS inverter IV02 includes a CMOS inverter having a PMOS transistor PM11 and a NMOS transistor NM11 connected in series between a first voltage source terminal supplied with a source voltage Vdd and a second voltage terminal supplied with the ground potential and a feedback resistor Rf.

Driving-current-controlling resistive elements r1 and r2 limiting a driving current for exciting the piezoelectric vibrator X2 are connected between the source of the PMOS transistor PM1 of the CMOS inverter and the first voltage source terminal and between the source of the NMOS transistor of the CMOS inverter and the second voltage source terminal, respectively.

The values of the capacitive elements C3 and C4 are selected as capacitance values which can compensate for the decrease in oscillation margin based on the decrease in mutual conductance Gm of the CMOS inverter which results from the interposing of the driving-current-controlling resistive elements r1 and r2.

In this case, due to the request for a decrease in power consumption from makers manufacturing the system LSI used to perform primary functions of a portable device, the mutual conductance Gm of the CMOS inverter should be reduced in order to reduce a driving current of a piezoelectric vibrator in an oscillation circuit. In addition, the mutual conductance Gm of the CMOS inverter is determined depending on the source voltage of the oscillation circuit and the CMOS structure.

Here, the oscillation margin M of the oscillation circuit is calculated by the following expression, where w represents an angular frequency of an oscillation frequency, C1 and C2 represent capacitances of capacitors externally connected between the input terminal and output terminal of the CMOS inverter serving as an oscillation gate of the oscillation circuit and the power source terminal, RL represents a negative resistance, R1 represents an effective resistance of the piezoelectric vibrator, and R1 (max) represents the maximum value of the effective resistance.

M=|−Gm|/(ω²C1·C2)×1/R1(max)=+RL/R1(max) (1)

The oscillation margin M needs to have a value equal to or greater than 5.

When it is reviewed from the viewpoint of the piezoelectric vibrator to accomplish the decrease in power consumption and the stabilization of oscillation in the oscillation circuit, the effective resistance R1 of the piezoelectric vibrator is a value determined by the requirement for a decrease in size of the piezoelectric vibrator and cannot be excessively lowered concerning the decrease in size of the piezoelectric vibrator.

Therefore, in order to keep the oscillation margin at such a value to stabilize the oscillation, it can be seen from Expression 1 that it can be realized by lowering the capacitance value of the capacitor constituting the load capacitance and being externally connected to the CMOS inverter, that is, the capacitance value of the load capacitance.

To meet such requirement, it is required that the piezoelectric vibrator of the oscillation circuit shown in FIG. 7 has a load capacitance CL (low load capacitance CL) suitable for the specification for low power consumption of the integrated circuit to be connected thereto.

In the piezoelectric vibrator of the oscillation circuit shown in FIG. 7, by determining the capacitance value of a capacitor constituting a load capacitor externally connected to the oscillation circuit of the integrated circuit along with the piezoelectric vibrator so that the load capacitance CL should be suitable for the specification for low power consumption of the integrated circuit to be connected to the piezoelectric vibrator, the desired low power consumption is accomplished. In this example, the load capacitance CL is reduced to 3 pF≦CL<5 pF (conventionally, 12.5 pF) to reduce the power consumption.

In the circuit shown in FIG. 7, the driving current (through-current) flowing in the PMOS transistor PM11 and the NMOS transistor NM11 of the CMOS inverter which is an oscillation gate exciting the piezoelectric vibrator X2 is suppressed by the driving-current-controlling resistive elements r1 and r2. The mutual conductance Gm of the CMOS inverter decreases with the decrease of the driving current, but the capacitive elements C3 and C4 connected between the input terminal XCIN and the output terminal XCOUT of the CMOS inverter and the voltage source terminal of the ground potential Vss have the capacitance values for compensating for the decrease in oscillation margin M due to the decrease in mutual conductance Gm of the CMOS inverter. That is, by reducing the capacitance values of the capacitive elements C3 and C4 so as to compensate for the decrease in oscillation margin M expressed by Expression 1 due to the decrease in mutual conductance Gm of the CMOS inverter, it is possible to obtain an excellent oscillation-starting characteristic and oscillation stability.

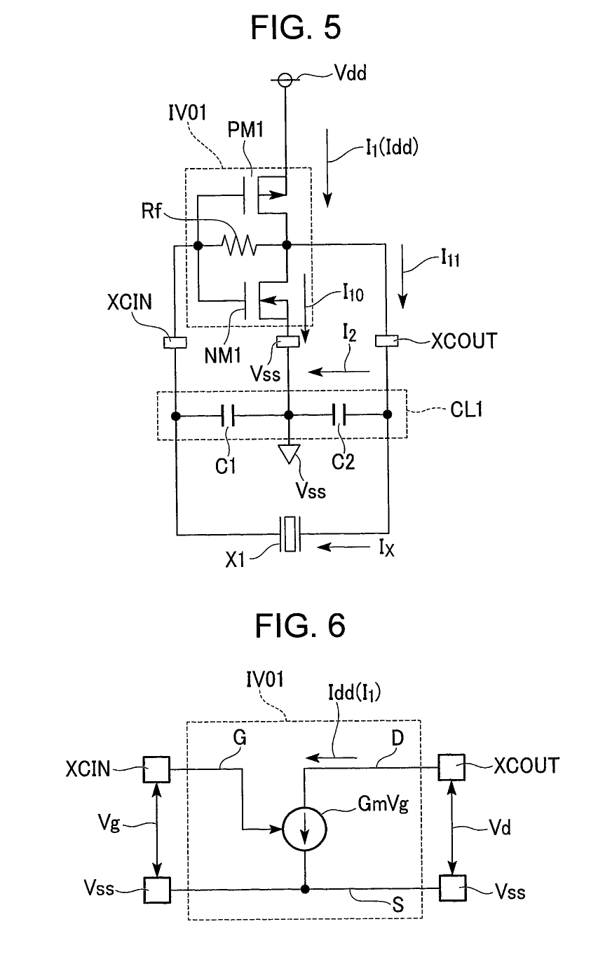

For example, when the mutual conductance of the CMOS inverter in the conventional circuit shown in FIG. 5 is Gm1, the mutual conductance of the CMOS inverter in the oscillation circuit shown in FIG. 7 is Gm2, Gm2=(1/2)·Gm1 is set, and the capacitance values of the capacitive elements C3 and C4 are set to C3=(1/√2)·C1 and C4=(1/√2)·C2, the conventional circuit shown in FIG. 5 and the oscillation circuit shown in FIG. 7 are equal to each other in driving performance, but the load capacitance can be reduced by reducing the mutual conductance Gm of the CMOS inverter.

Since the charging and discharging current flowing in the capacitive elements C3 and C4 connected between the input terminal and the output terminal of the CMOS inverter constituting the load capacitance of the crystal vibrator as the piezoelectric vibrator and the voltage source terminal is proportional to the capacitance values of the capacitive elements C3 and C4, the charging and discharging current flowing in the capacitive elements C3 and C4 having small capacitance values is reduced. Accordingly, the power consumption is reduced with the reduction in charging and discharging current.

In this way, by constructing the oscillation circuit including a piezoelectric vibrator having a small load capacitance, it is possible to accomplish the oscillation-starting characteristic and the oscillation stability with the improvement of the negative resistance RL and to accomplish the decrease in power consumption with the reduction in charging and discharging current.

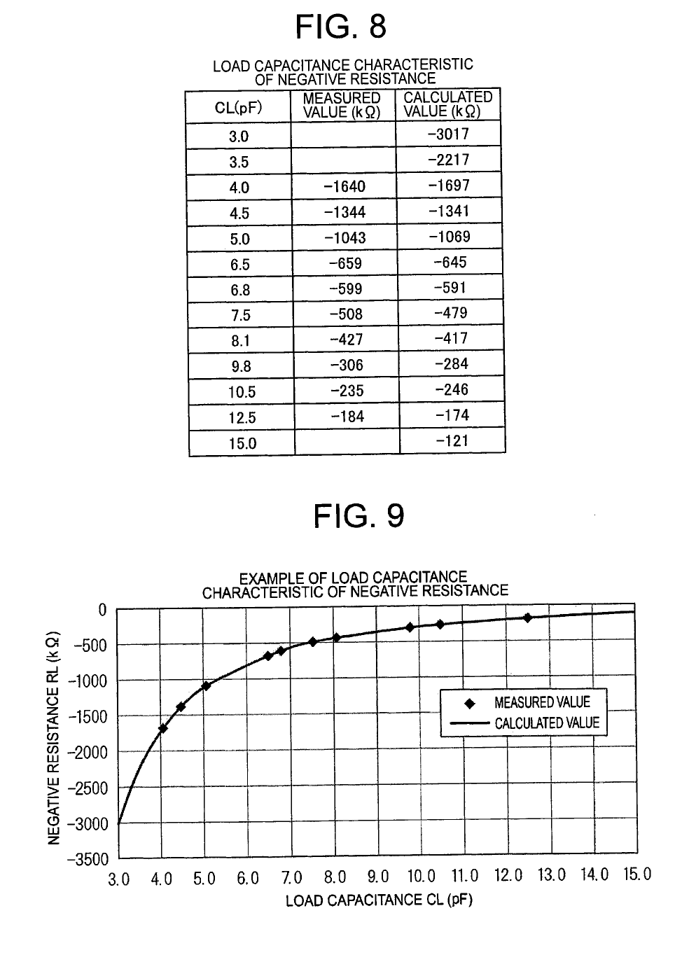

The measured values and the calculated values of characteristic data representing the relation of the negative resistance RL with respect to the load capacitance CL are shown in FIG. 8 and the graph thereof is shown in FIG. 9. As can be clearly seen from the drawings, the measured values and the calculated values are equal to each other. Accordingly, when the negative resistance RL values corresponding to the load capacitances CL1 and CL2 are RL1 and RL2, the increment ΔRL of the negative resistance RL depending on the load capacitance CL is expressed by Expression 2.

ΔRL=RL2/RL1=(CL1/CL2)²,CL1>CL2 (2)

As can be clearly seen from the above expression, the negative resistance RL is inversely proportional to the square of the load capacitance CL.

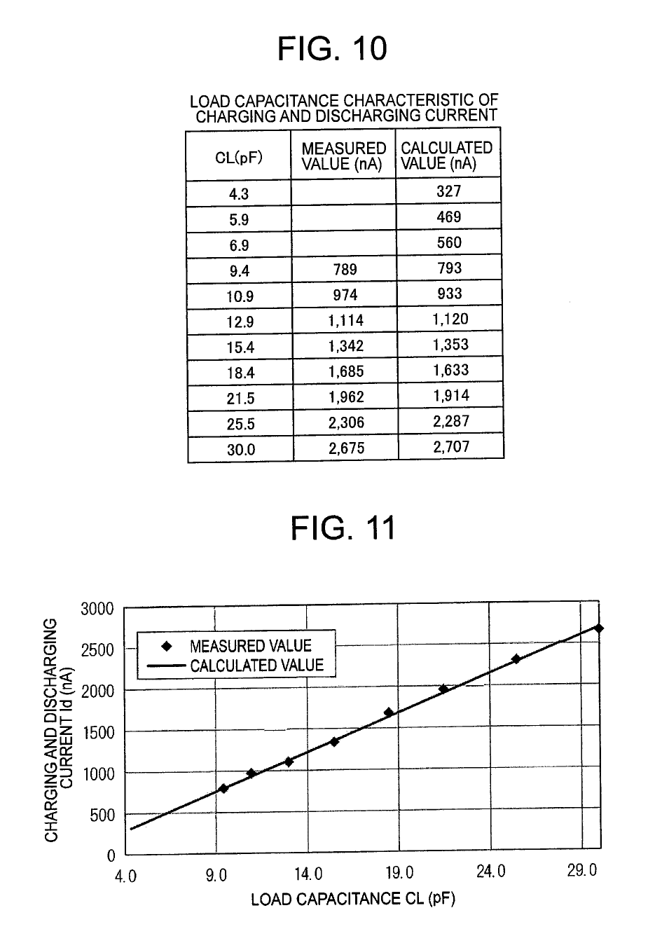

Characteristic data representing the relation between the load capacitance CL and the charging and discharging current Id (corresponding to I₄ in FIG. 7) is shown in FIG. 10 and the graph thereof is shown in FIG. 11. It can be seen from the drawings that the measured values and the calculated values of the value of the charging and discharging current Id with respect to the load capacitance CL are equal to each other.

Accordingly, when the values of the charging and discharging current Id corresponding to the load capacitances CL1 and CL2 are Id1 and Id2, the decrement ΔId of the charging and discharging current Id depending on the load capacitance CL is expressed by Expression 3.

ΔId=Id2/Id1=CL2/CL1,CL1>CL2 (3)

As can be clearly seen from the above expression, the charging and discharging current Id is proportional to the load capacitance CL.

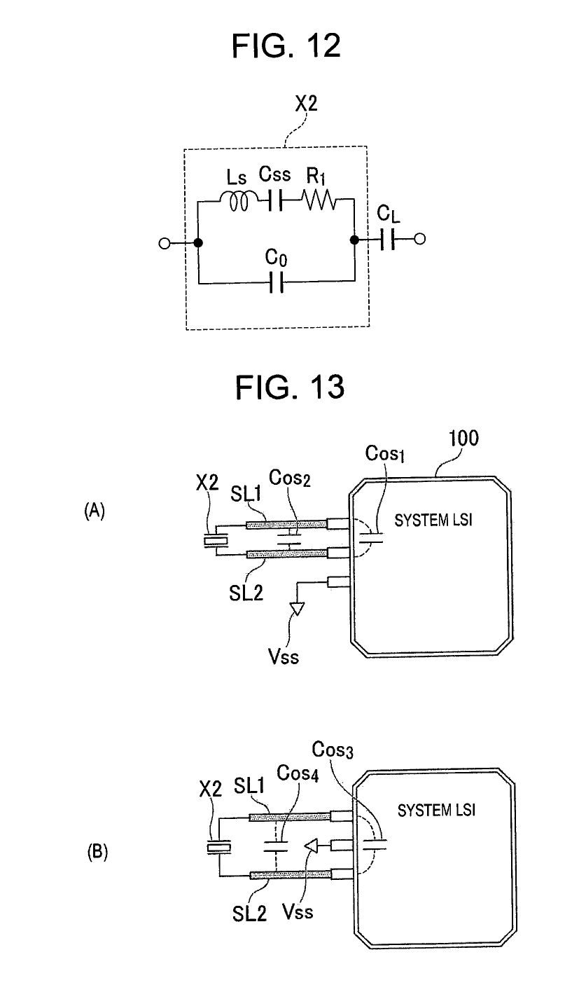

The limitation of the load capacitance CL when the piezoelectric vibrator having a low load capacitance CL is used will be described below. The equivalent circuit of the piezoelectric vibrator is shown in FIG. 12. In FIG. 12, the load capacitor CL is connected in series to the piezoelectric vibrator X2. As known well, the piezoelectric vibrator X2 (for example, crystal vibrator) is expressed as a circuit in which an inter-electrode capacitor C0 is parallel-connected to a series resonance circuit of inductance Ls, capacitance Css, and resistance R1 equivalently representing the mechanical resonance due to the piezoelectric effect.

The theoretical limitation of the capacitance value of the load capacitor CL with respect to the inter-electrode capacitance C0 in the equivalent circuit shown in FIG. 12 is C0<CL<∞, where C0=1.3 pF. The limitation of the capacitance value of the load capacitor CL in the state where the piezoelectric vibrator X2 is connected to the system LSI 100 of a portable device and the like will be described below. As shown in FIG. 13(A), the capacitance between the oscillation input and output terminals of the oscillation gate formed in the system LSI 100 is Cos1 and the capacitance between the signal lines is Cos2, the limitation of the capacitance of the load capacitor CL is C0+Cos1+Cos2<CL<∞.

The lower limit of the load capacitance CL increases by connecting the piezoelectric vibrator to the system LSI 100 in this way. However, as shown in FIG. 13(B), when the voltage source terminal Vss set to the ground potential is located at the centers of the signal lines SL1 and SL2 and is grounded and the distance between the terminals connected to the piezoelectric vibrator X2 increases up to double the distance in the case shown in FIG. 13(A) at the time of reducing the capacitance Cos1 between the oscillation input and output terminals and the capacitance Cos2 between the signal lines, the capacitance Cos4 between the signal lines is reduced to a half the capacitance Cos2 between the signal lines in the case shown in FIG. 13(A) and the capacitance Cos2 between the oscillation input and output terminals becomes negligible, whereby the effect of reducing the load capacitance is great. That is, in the state shown in FIG. 13(B), the limitation of the load capacitance CL is C0+Cos4<CL<∞, Cos4=0.4 pF.

The limitation of the resistance value of the feedback resistance Rf when the oscillation gate of the oscillation circuit having the piezoelectric vibrator shown in FIG. 7 includes the CMOS gate will be described below. In the oscillation circuit, since the cutoff frequency Fc at which the negative resistance RL is 0Ω is proportional to the mutual conductance Gm and is inversely proportional to the product of the feedback resistance Rf and the square of the load capacitance CL, the cutoff frequency Fc at which the negative resistance RL is 0Ω is expressed by Expression 4.

Fc∝Gm/(Rf×CL²) (4)

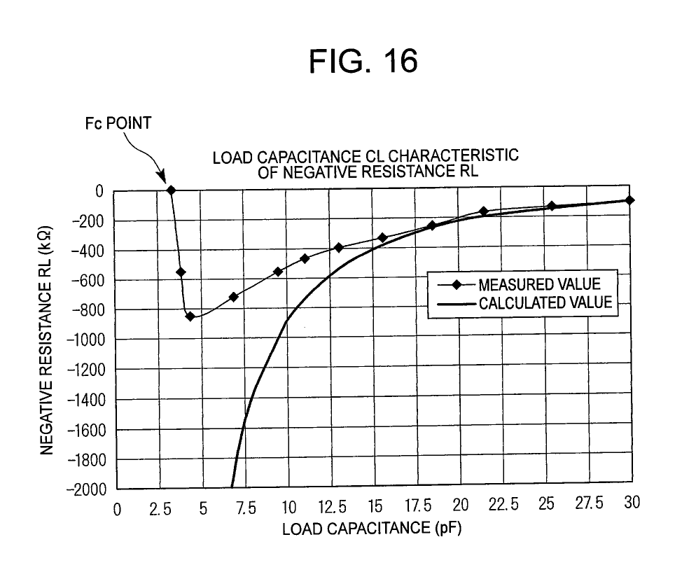

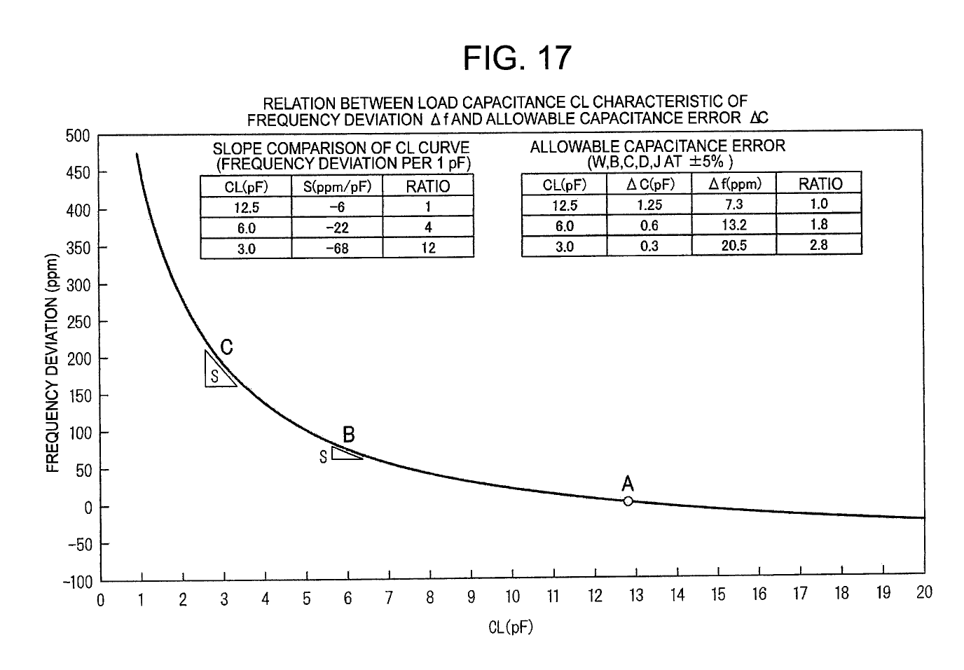

The cutoff frequency Fc increases when the value of the load capacitance CL decreases in Expression 4, and the negative resistance RL rapidly decreases when the cutoff frequency gets close to the oscillation frequency of the oscillation circuit. Characteristic data representing the relation of the load capacitance CL and the negative resistance RL with respect to the cutoff frequency Fc is shown in FIG. 15 and the graph representing the characteristic of the negative resistance RL with respect to the load capacitance CL is shown in FIG. 16.

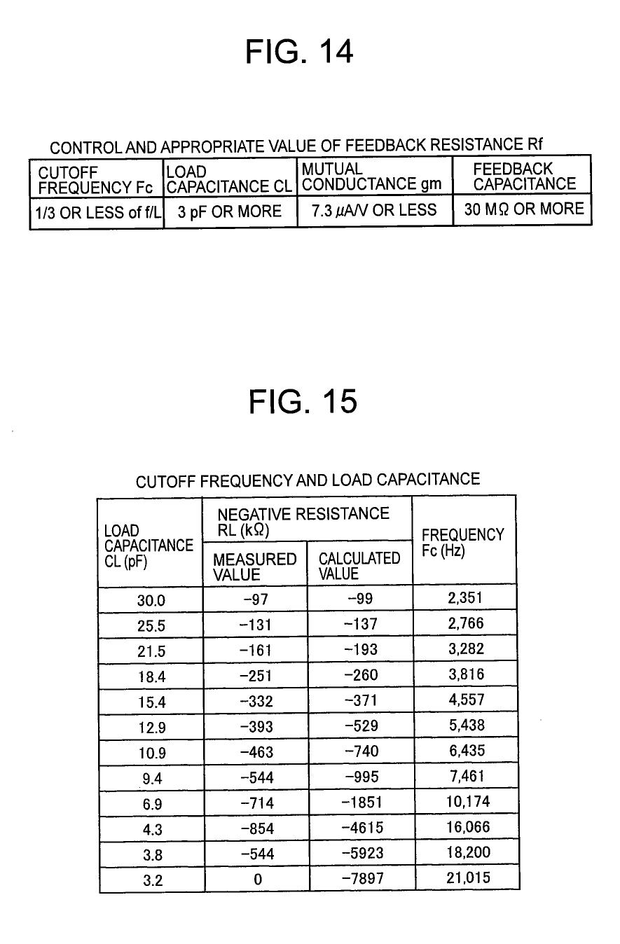

In the oscillation circuit in which the decrease in power consumption is accomplished, the mutual conductance Gm is set to be low and thus the piezoelectric vibrator having the load capacitance CL with a small capacitance value can be used in a stable state by setting the feedback resistance Rf to be as large as possible. An example of the appropriate value of the feedback resistance Rf when the cutoff frequency Fc is set to ⅓ or less of the oscillation frequency fL of the oscillation circuit is shown in FIG. 14.

In this way, in the oscillation circuit shown in FIG. 7, by determining the capacitance values of the capacitive elements (capacitors) C3 and C4 constituting a load capacitor externally connected to the oscillation circuit of the integrated circuit along with the piezoelectric vibrator so that the load capacitance CL should be suitable for the specification for low power consumption of the integrated circuit to be connected to the piezoelectric vibrator, the desired low power consumption is accomplished. By constructing an oscillation circuit having a piezoelectric vibrator with a low load capacitance, it is possible to accomplish the oscillation-starting characteristic and the oscillation stability based on the improvement of the negative resistance RL and to accomplish the great decrease in power consumption based on the decrease in charging and discharging current.

### (Configuration of Oscillation Circuit According to the Invention)

According to the oscillation circuit shown in FIG. 7, it is possible to construct an oscillation circuit having a piezoelectric vibrator with a lower load capacitance CL (3 pF to 5 pF) than the conventional load capacitance CL (12.5 pF), thereby accomplishing the decrease in power consumption based on the decrease in charging and discharging current.

However, due to the decrease in load capacitance CL, the problems with the allowable capacitance error ΔC of the load capacitance CL and the frequency deviation Δf of the oscillation frequency become remarkable.

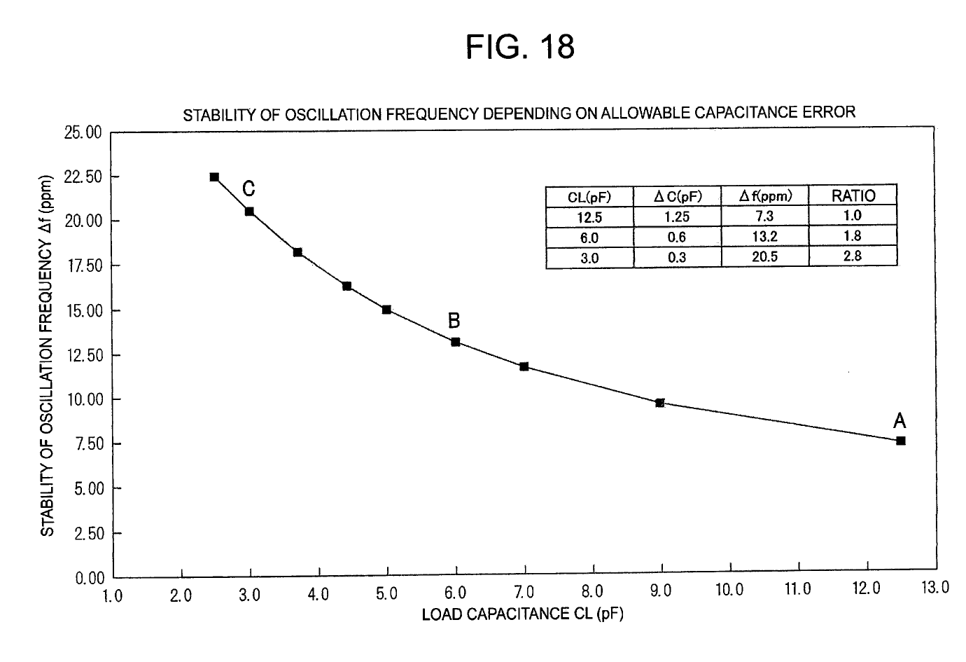

As shown in FIG. 18, regarding the oscillation frequency stability Δf (ppm) when the load capacitance CL varies by ΔC (±5%) which is the normal allowable capacitance error, when the load capacitance CL is 12.5 pF, ΔC is 1.25 pF and the oscillation frequency stability Δf is 7.3 ppm. When the load capacitance CL is 6 pF, ΔC is 0.6 pF and the oscillation frequency stability Δf is 13.2 ppm. When the load capacitance CL is 3 pF, ΔC is 0.3 pF and the oscillation frequency stability Δf is 20.5 ppm.

That is, when the frequency stability Δf (7.3 ppm/pF) at the load capacitance CL of 12.5 pF is assumed as 1 and the load capacitance CL is 6 pF, the frequency deviation (ppm) is generated at 1.8 times the rate with 12.5 pF. When the load capacitance CL is 3 pF, the frequency deviation (ppm) is generated at 2.8 times the rate with 12.5 pF.

In this way, with the low load capacitance CL (for example, 3 pF), the frequency deviation increases by 2.8 times that with 12.5 pF. Accordingly, in order to reduce the load capacitance CL (the decrease in CL), it is necessary to improve the oscillation frequency stability with respect to the allowable capacitance error of the load capacitance CL.

A goal of the invention is to provide an oscillation circuit which can solve the problem with the frequency stability caused at the time of reducing the load capacitance CL of the piezoelectric vibrator connected to the oscillation circuit. An oscillation circuit according to an embodiment of the invention will be described below.

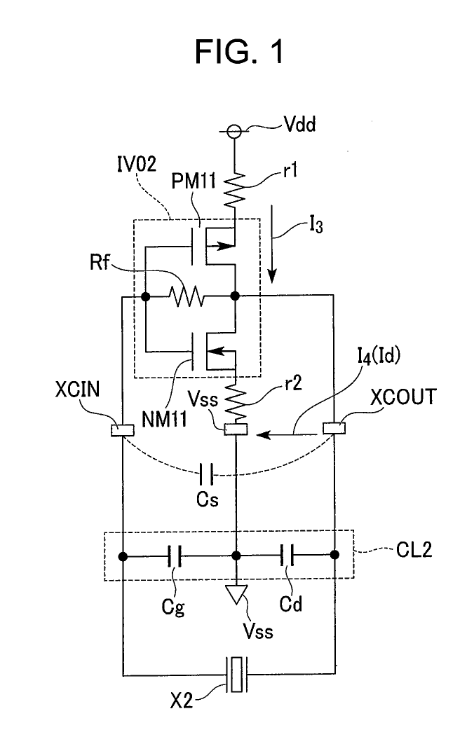

FIG. 1 is a diagram illustrating the configuration of an oscillation circuit according to an embodiment of the invention.

The oscillation circuit according to the embodiment of the invention shown in FIG. 1 basically has the same configuration as the oscillation circuit shown in FIG. 7 and is characterized in the method of selecting the capacitance of the capacitive elements (capacitors) Cg and Cd externally connected between the input terminal XCIN and the output terminal XCOUT of the CMOS inverter and the voltage source terminal Vss. Accordingly, the common elements are referenced by like reference numerals and the description thereof is not made repeatedly.

In FIG. 1, the floating capacitance Cs is a combined floating capacitance caused by the CMOS semiconductor substrate, the signal lines, and the like and is, for example, in the range of 1 to 5 pF (where the floating capacitance Cs is preferably in the range of 1 to 4 pF in view of reducing the power consumption). It is known that the floating capacitance Cs varies depending on the number of layers in the semiconductor substrate, is about 1 pF in a single-layered substrate, is about 2 pF in a two-layered substrate, and is about 3 pF in a three-layered substrate.

Specifically, in the conventional oscillation circuit shown in FIG. 5, the capacitance Cext (=Cg×Cd/(Cg+Cd)) of the capacitive element (capacitor) matched in oscillation frequency and externally mounted with a general load capacitance of 12.5 pF is collected in the range of 9 pF to 11 pF as the measurement result. Accordingly, it is estimated that the floating capacitance Cs is in the range of about 1.5 pF to 3.5 pF. It is thought that a margin of 0.5 pF is added to the measured values and the effective range of the floating capacitance Cs is preferably 1 pF≦Cs≦4 pF.

Since the floating capacitance Cs deteriorates the characteristic of the oscillation circuit, it was conventionally considered that the floating capacitance Cs is set to be as small as possible, but there was a limit therein. Therefore, the inventor found that the oscillation frequency stability could be improved actively using the floating capacitance Cs through experiments and studies.

That is, in the oscillation circuit according to the invention, it was proved that the oscillation frequency stability with respect to the allowable capacitance error ΔC of the load capacitance CL is improved by selecting the capacitance values of the capacitive elements (capacitors) Cg and Cd so that the load capacitance CL satisfies the following relational expression actively using the floating capacitance Cs.

CL=Cs+Cg×Cd/(Cg+Cd)

That is, since the load capacitance CL is the sum of the floating capacitance Cs and the capacitance value Cext (=Cg×Cd/(Cg+Cd)) of the external capacitive element (capacitor), the capacitance value Cext of the external capacitive element (capacitor) can be selected as a difference value between the load capacitance CL and the floating capacitance Cs (1 pF to 4 pF).

When the capacitance values of the capacitive elements (capacitors) Cg and Cd are selected so as to satisfy the relational expression of “CL=Cs+Cg×Cd/(Cg+Cd)”, it means that the load capacitance CL of the piezoelectric vibrator is matched with the load capacitance of the oscillation circuit as viewed from the piezoelectric vibrator.

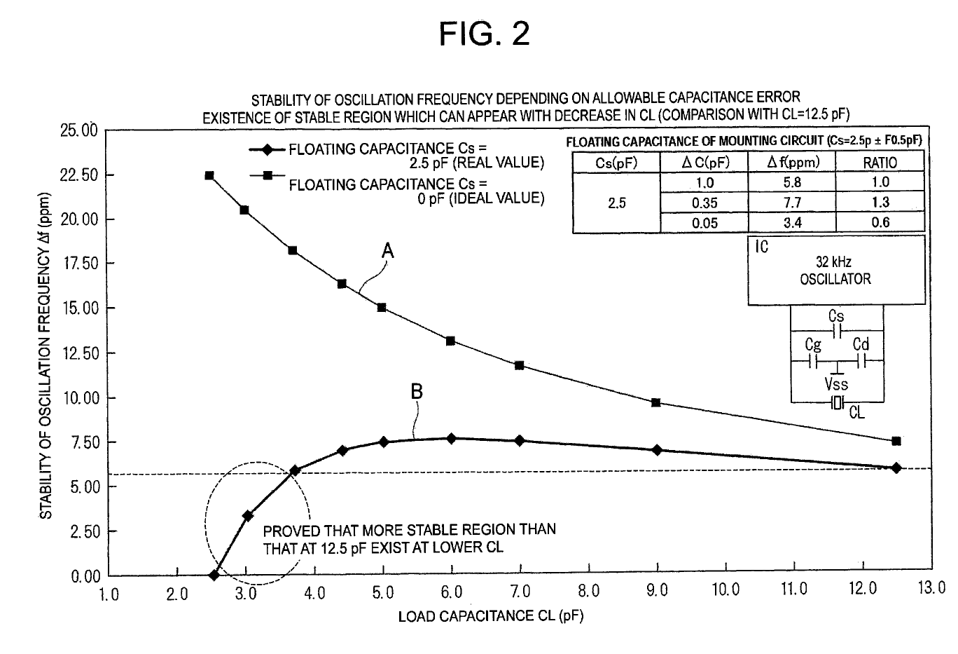

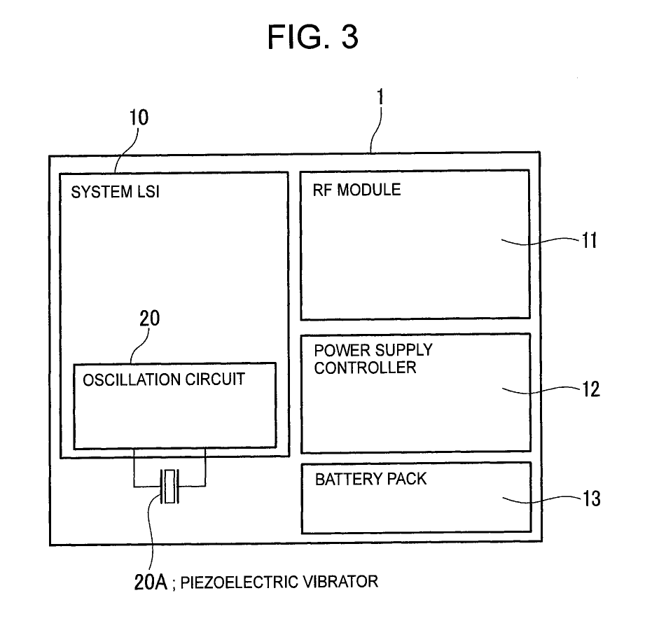

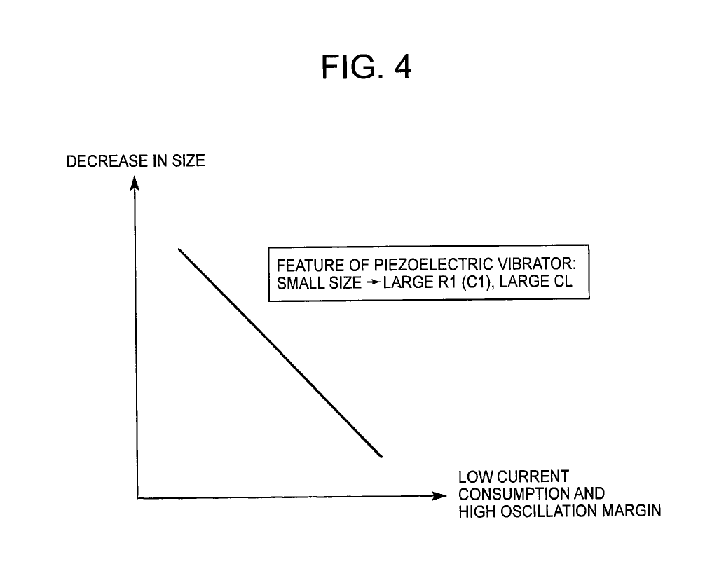

FIG. 2 is a diagram illustrating the oscillation frequency stability with respect to the allowable capacitance error ΔC of the load capacitance CL.

In FIG. 2, characteristic curve A indicates the conventional oscillation circuit (see FIG. 7) disclosed in PTL 3, that is, the circuit in which only the decrease in load capacitance CL is accomplished. Characteristic curve B indicates the oscillation circuit according to the invention shown in FIG. 1, that is, the oscillation circuit in which the decrease in load capacitance CL is accomplished and the oscillation frequency stability is improved.

Characteristic curve A represents data of the oscillation frequency stability Δf (ppm) when the floating capacitance Cs is 0 pF (ideal value) and the load capacitance CL varies in ±5% (normal allowable error range) and is the same as shown in FIG. 18. In characteristic curve A, the frequency deviation at the low load capacitance CL (3 pF) in the conventional oscillation circuit increases to 2.8 times that at 12.5 pF.

On the other hand, characteristic curve B represents an example where the capacitance values of the capacitive elements (capacitors) Cg and Cd in the circuit shown in FIG. 1 are selected so that the load capacitance CL satisfies the relational expression of “CL=Cs+Cg×Cd/(Cg+Cd)” actively using the floating capacitance Cs.

As indicated by characteristic curve B, it is proved that the frequency stability in the region (around about 3 pF) surrounded with a broken circle and having a low load capacitance CL is more stable than that at the load capacitance CL of 12.5 pF.

As described above, the floating capacitance Cs varies depending on the number of layers in the substrate and the piezoelectric vibrator is used so that the load capacitance CL is in the range of 3 pF to 6 pF depending on the floating capacitance Cs, for example, in the range of 1 pF to 5 pF. For example, 3 pF, 3.7 pF, 4.4 pF, and 6 pF can be normally selected as the load capacitance CL.

The stability of the oscillation frequency will be described below.

The oscillation frequency stability Δf is a difference between the oscillation frequency fosc and the nominal frequency Fo. Accordingly, in the equivalent circuit of the oscillation circuit shown in FIG. 12, when the series resonance frequency of the oscillation circuit is fr and the capacitance value of the external capacitive element (capacitor) is Cext, the oscillation frequency stability is expressed by Expression 5.

Δf=fosc−Fo

=frx(Css/(2×(Co+Cs+Cext))−Css/(2×(Co+CL))) (5)

In Expression 5, fosc=Fo when CL=Cs+Cext. For example, the external capacitive element (capacitor) Cext generally has an allowable capacitance error of ±5% or ±10%. Accordingly, when the allowable capacitance error is −ΔCext, the load capacitance decreases (CL>Cs+Cext−ΔCext). Accordingly, in Expression 5, the oscillation frequency stability Δf is greater than zero. That is, like Δf=fosc−Fo>0, it means that the frequency precedes. On the other hand, when the allowable capacitance error is +ΔCext, the load capacitance increases (CL<Cs+Cext+ΔCext). Accordingly, in Expression 5, the oscillation frequency stability Δf is smaller than zero. That is, like Δf=fosc−Fo<0, it means that the frequency lags.

In this way, a deviation is caused in the oscillation frequency depending on the allowable capacitance error of the external capacitive element (capacitor), whereby the stability of the oscillation frequency decreases.

When the allowable capacitance error of the external capacitive element (capacitor) Cext is −ΔCext, the oscillation frequency deviation Δf/f precedes as described above and is represented by [Δf/f]max which is expressed by Expression 6.

[Δf/f]max=Css/(2×(Co+Cs+Cext−ΔCext)) (6)

Similarly, when the allowable capacitance error of the external capacitive element (capacitor) Cext is +ΔCext, the oscillation frequency deviation Δf/f lags as described above and is represented by [Δf/f]min which is expressed by Expression 7.

[Δf/f]min=Css/(2×(Co+Cs+Cext+ΔCext)) (7)

The oscillation frequency deviation (Δf)_{CL} with respect to the variation of the load capacitance CL can be expressed by Expression 8 from Expressions 6 and 7.

(Δf)_{CL}=[Δf/f]max−[Δf/f]min (8)

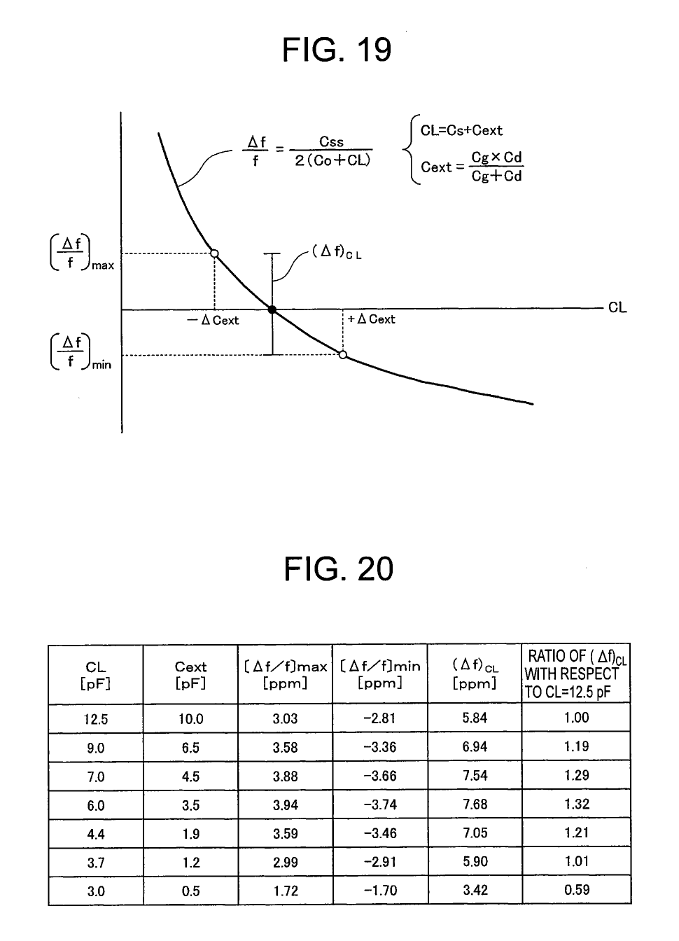

Expressions 6 to 8 can be expressed as a graph as shown in FIG. 19. FIG. 19 is a diagram illustrating the characteristics of the load capacitance CL and the oscillation frequency deviation (Δf). As shown in FIG. 19, compared with the oscillation frequency when the external capacitive element (capacitor) Cext has no allowable capacitance error, the oscillation frequency deviation Δf/f precedes at −ΔCext, the oscillation frequency deviation Δf/f lags at +ΔCext, and thus the oscillation frequency deviation (Δf)_{CL} is generated.

FIG. 20 is a diagram illustrating characteristic data representing the relation of the oscillation frequency deviation depending on the allowable capacitance error of the external capacitive element (capacitor) at a floating capacitance of Cs=2.5 pF. As shown in FIG. 20, when the load capacitance CL is in the range of 12.5 pF to 3 pF, the capacitance of the external capacitive element (capacitor) Cext is in the range of 10 pF to 0.5 pF. FIG. 20 shows the values of [Δf/f]max, [Δf/f]min, and (Δf)_{CL} when the external capacitive element (capacitor) Cext has an allowable capacitance error of ±5%. As shown in FIG. 20, in comparison with the oscillation frequency deviation (Δf)_{CL} at a load capacitance of 12.5 pF which is generally used, the ratio at the load capacitance of 3.7 pF is equal and the ratio at the load capacitance of 3 pF is low, that is, the oscillation frequency deviation (Δf)_{CL} decreases. The range of a low load capacitance CL which is more stable than at 12.5 pF which is generally used and which is indicated by characteristic curve B in FIG. 2 is 3.7 pF or less as shown in FIG. 20.

That is, by selecting the capacitance values of the capacitive elements Cg and Cd actively using the floating capacitance Cs so as to satisfy the relational expression of “CL=Cs+Cg×Cd/(Cg+Cd)”, the frequency stability equivalent to or more excellent than that at 12.5 pF can be obtained even when the load capacitance CL decreases.

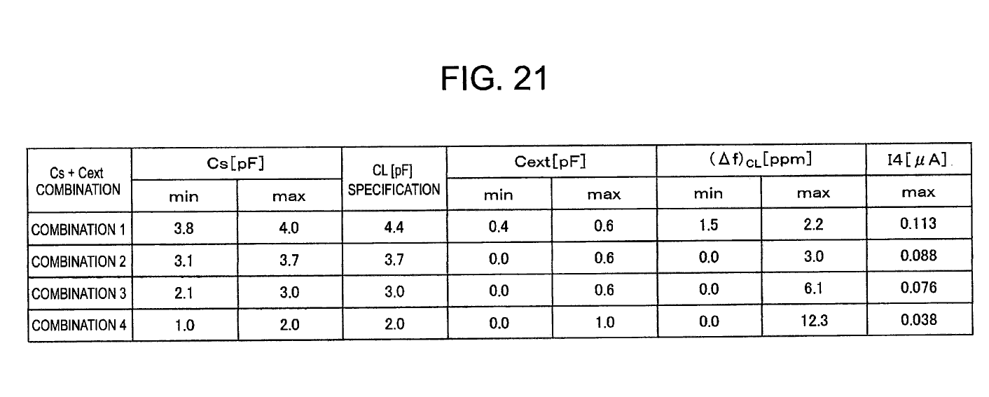

Examples of a combination of the floating capacitance Cs and the low load capacitance CL in which the oscillation frequency deviation (Δf)_{CL} is more stable that that at a load capacitance of CL=12.5 pF are shown in FIG. 21. The floating capacitance Cs is in the range of 1 pF to 4 pF as described above. For example, in FIG. 21, combination 1 includes a floating capacitance of Cs=3.8 pF to 4 pF and a load capacitance of CL=4.4 pF in the oscillation circuit from the specification. Accordingly, the capacitance of the external capacitive element (capacitor) Cext is in the range of 0.4 pF to 0.6 pF. The oscillation frequency deviation (Δf)_{CL} is in the range of 1.5 ppm to 2.2 ppm from the calculation under this condition. The charging and discharging current I4 in FIG. 1 is 0.113 μA. At the load capacitance of CL=2 pF of combination 4, the low load capacitance CL in this embodiment is set to the range of 3 pF to 6 pF, because the maximum value of the oscillation frequency deviation (Δf)_{CL} is 12.3.

Since it is necessary for realizing the low load capacitance that the capacitance value of the external capacitive element (capacitor) Cext used should be low, a capacitor with a capacitances every 0.1 pF are used in this embodiment.

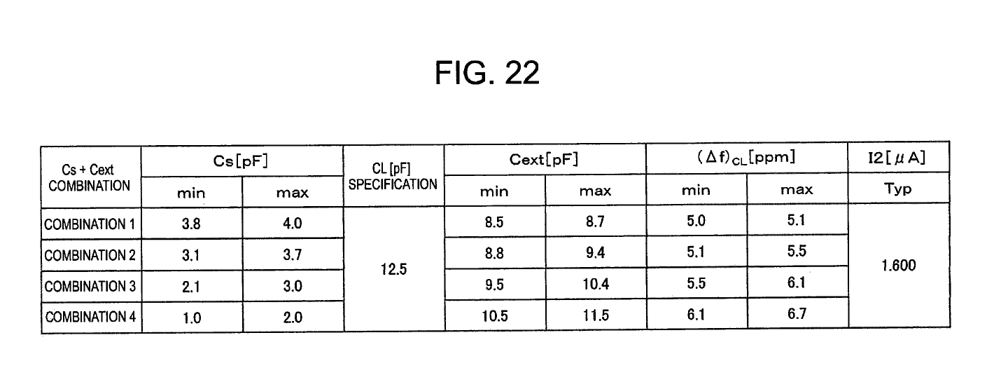

For reference, the combinations of the floating capacitance Cs and the external capacitive element (capacitor) at a load capacitance of CL=12.5 pF generally used and examples of the oscillation frequency deviation (Δf)_{CL} are shown in FIG. 22. In this case, the combinations in which the load capacitance is constant at CL=12.5 pF and the floating capacitance Cs for comparison is the same as the low load capacitance shown in FIG. 21 are selected. I2 represents the charging and discharging current in the conventional oscillation circuit shown in FIG. 5. As shown in FIG. 22, even when the floating capacitance Cs varies, the load capacitance CL=12.5 pF is characterized in that the variation width of the oscillation frequency deviation (Δf)_{CL} is small.

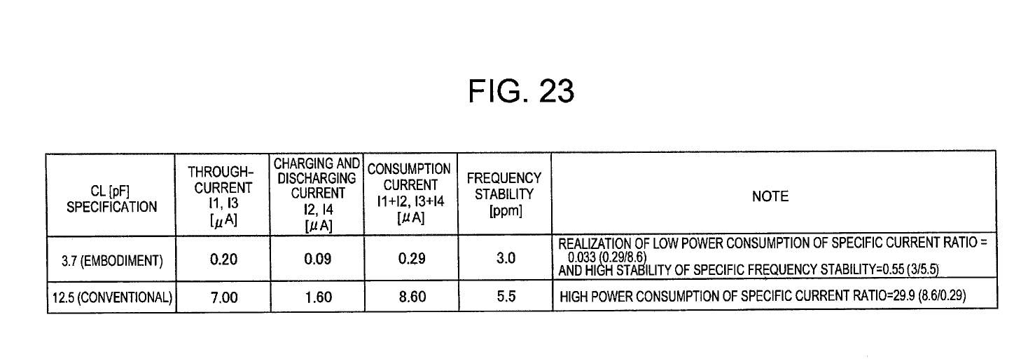

FIG. 23 is a diagram illustrating the comparison result of combination 2 (with a load capacitance of CL=3.7 pF) shown in FIG. 21 and combination 2 shown in FIG. 22, which include the same floating capacitance. As shown in FIG. 23, when the low load capacitance of CL=3.7 pF satisfying the relational expression “CL=Cs+Cg×Cd/(Cg+Cd)” is set, it was confirmed that all items of the through-current I₁, the charging and discharging current I₂, the consumption current I₁+I₂, and the oscillation frequency stability (deviation) (Δf)_{CL} are more excellent than those at the load capacitance of CL=12.5 pF.

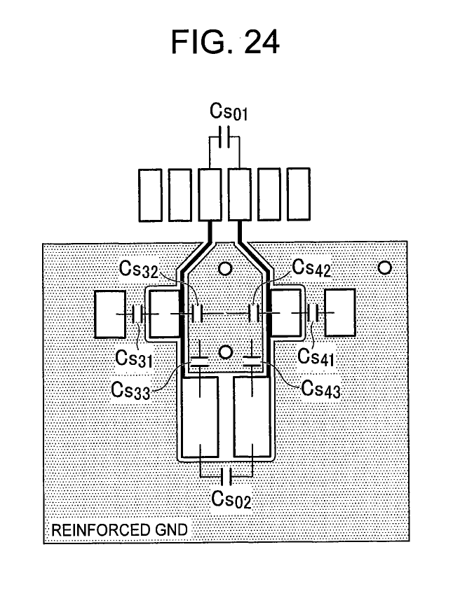

Since the load capacitance is low, it is possible to reduce the loss of the floating capacitance Cs by reinforcing the GND and laying out the substrate as shown in FIG. 24 so as to guarantee the resistance to external noise. This is because the capacitance with the smaller floating capacitance Cs is much smaller as can be seen from Expressions 9 and 10, comparing the floating capacitance Cs with the capacitances between the terminals of the external capacitive element (capacitor) and the GND and between the terminals of the piezoelectric vibrator and the GND.

Cs=Cs₀+((Cs₃×Cs₄)/(Cs₃+Cs₄))(9)

Cs₀<<Cs₃=Cs₄ (10)

In Expressions 9 and 10, Cs₀, Cs₃, and Cs₄ are expressed by Expressions 11 to 13.

Cs₀=Cs₀₁+Cs₀₂ (11)

Cs₃=Cs₃₁+Cs₃₂+Cs₃₃+ . . . Cs₃ₙ (12)

Cs₄=Cs₄₁+Cs₄₂+Cs₄₃+ . . . Cs₄ₙ (13)

According to the above-mentioned configuration of the invention, by selecting the load capacitance CL in the oscillation circuit with reduced power consumption (FIG. 7) so as to satisfy “CL=Cs+Cg×Cd/(Cg+Cd)”, it is possible to implement an oscillation circuit with reduced power consumption and enhanced oscillation frequency stability.

While the embodiment of the invention has been described hitherto, the invention is not limited to the oscillation circuit described and shown above, but may be modified in various forms without departing from the concept of the invention.

What is claimed is:

1. A piezoelectric vibrator which is connected to an oscillation circuit formed on an integrated circuit,
wherein the piezoelectric vibrator has a load capacitance CL substantially equal to a floating capacitance Cs formed by the oscillation circuit of the integrated circuit or a load capacitance CL larger by a predetermined capacitance than the floating capacitance Cs, and
wherein a load capacitance of the oscillation circuit connected to the piezoelectric vibrator is matched with the load capacitance CL of the piezoelectric vibrator by the use of a capacitive element.

2. The piezoelectric vibrator according to claim 1, wherein the floating capacitance Cs of the oscillation circuit is in the range of about 1 pF to about 4 pF, and
wherein the load capacitance CL is in the range of about 3 pF to about 5 pF.

3. An oscillation circuit comprising:
a CMOS semiconductor circuit formed on an integrated circuit; and
a piezoelectric vibrator connected to the CMOS semiconductor circuit,
wherein the piezoelectric vibrator has a load capacitance CL substantially equal to a floating capacitance Cs formed by the CMOS semiconductor circuit or a load capacitance CL larger by a predetermined capacitance than the floating capacitance Cs, and
wherein a capacitive element that matches a load capacitance of the CMOS semiconductor circuit connected to the piezoelectric vibrator with the load capacitance CL of the piezoelectric vibrator is provided.

4. The oscillation circuit according to claim 3, wherein the floating capacitance Cs formed by the CMOS semiconductor circuit is in the range of about 1 pF to about 4 pF, and
wherein the load capacitance CL is in the range of about 3 pF to about 5 pF.

5. The oscillation circuit according to claim 3, wherein the CMOS semiconductor circuit includes a CMOS inverter, the piezoelectric vibrator is connected between input and output terminals of the CMOS inverter, and the oscillation circuit further comprises a first capacitive element Cg connected between the input terminal of the CMOS inverter and the ground potential Vss and a second capacitive element Cd connected between the output terminal of the CMOS inverter and the ground potential Vss, and
wherein the capacitances of the first capacitive element Cg and the second capacitive element Cd are determined so that the load capacitance CL of the piezoelectric vibrator satisfies a relational expression of CL=Cs+Cg×Cd/(Cg+Cd).
